(19) United States
(12) Patent Application Publication
(10) Pub. No.: US 2004/0031441 A1
(43) Pub. Date: Feb. 19, 2004

(54) High-pressure treatment apparatus and high-pressure treatment method

(76) Inventors: Yusuke Muraoka, Kyoto (JP); Takashi Miyake, kyoto (JP); Kimitsugu Saito, Kyoto (JP); Takahiko Ishii, Hyogo (JP); Yoshihiko Sakashita, Hyogo (JP); Katsumi Watanabe, Hyogo (JP)

Correspondence Address: Ostrolenk Faber Gerb & Soffen, 1180 Avenue of the Americas, New York, NY, 10036-8403, US

(21) Appl. No.: 10/380,610

(22) PCT Filed: Jul. 22, 2002
(86) PCT No.: PCT/JP02/07401

(30) Foreign Application Priority Data
Jul. 25, 2001 (JP) 2001-224118
Jul. 11, 2002 (JP) 2002-202343

(51) Int. Cl. C23C 16/00

(52) U.S. Cl. 118/715

(57) ABSTRACT

A processing fluid is not only supplied toward a surface side of a substrate (W) from supply nozzles (13, 13), but also flow directions (R1, R1) of the processing fluid supplied from the respective supply nozzles 13 deviate from each other within the surface of the substrate (W). Therefore, a whirling flow (TF) of the processing fluid is formed over the surface of the substrate (W) and the processing fluid comes into contact with the surface of the substrate (W), thereby performing a predetermined surface treatment (e.g. cleaning, first rinsing, second rinsing and drying).

### TECHNICAL FIELD

The present invention relates to a high-pressure processing apparatus and a high-pressure processing method which cause a high-pressure fluid or a mixture of a high-pressure fluid and a chemical agent, as a processing fluid, to come into contact with a surface of an object-to-be-processed such as a substrate, thereby performing a predetermined surface treatment (e.g. developing, cleaning, drying or the like) for the surface of the object-to-be-processed.

### BACKGROUND ART

While fine patterning of semiconductor devices has been rapidly progressed in recent years, this endeavor has led to a new problem in substrate processing. For instance, when a resist applied to a substrate is to be patterned in order to create fine patterns, a developing process, a cleaning process and a drying process are executed in this order. In the case of alkali developing, during the developing process for developing the resist applied to the substrate, an alkaline solution is used for removing an unnecessary amount of the resist, a cleaning fluid such as deionized water is used during the cleaning process for removing the alkaline solution (for stopping the developing), and during the drying process, the substrate is rotated to make centrifugal force act upon the cleaning fluid which remains on the substrate so that the cleaning fluid is removed from the substrate to be dried (spin drying). During the drying process among these processes, if an interface between the cleaning fluid and gas appears on the substrate as the drying proceeds and this interface shows itself in a gap between the fine patterns of the semiconductor device, surface tension due to viscosity of the cleaning fluid pulls the fine patterns toward each other and accordingly destroys the fine patterns, which is a problem.

In addition, it is conceivable that the destruction of fine patterns is also caused by fluid resistance at the time of throwing off the cleaning fluid, applied pressure resulted from discharging the cleaning fluid from the fine patterns, and air resistance or centrifugal force due to high-velocity revolution over 3000 rpm.

In order to solve the above-mentioned problem, conventionally proposed is a technique of a high-pressure cleaning process which sets up a substrate within a pressure vessel and uses a supercritical fluid (hereinafter referred to as “SCF”) having low viscosity and high diffusion property. One example of the conventional technique is a cleaning device described in Japanese Patent Application Laid-Open Gazette No. H8-206485. In the cleaning device, after an object-to-be-cleaned (object-to-be-processed) such as a substrate is loaded into a cleaning bath (pressure vessel), the SCF is introduced into the cleaning bath to clean the object-to-be-cleaned. In this cleaning device, laminar flow ducts or gratings are disposed at opening portions of the cleaning bath in order to achieve uniformity of the cleaning process. The laminar flow duct or grating has a plurality of holes which are arranged at regular intervals. The SCF flows into and out of the cleaning bath through the holes. In this manner, the SCF flows in a predetermined direction on the surface of the object-to-be-cleaned, thereby forming a laminar flow. As just described, it is possible to clean the object-to-be-cleaned evenly by flowing the SCF evenly inside the cleaning bath.

However, in the case where the laminar flow of the SCF is simply formed and the object-to-be-processed is just exposed to the laminar flow, desired uniformity can not be achieved although certain degree of the uniformity is realized. In addition, it is desired to further reduce processing time to enhance throughput.

The present invention has been made in view of the problems above, and accordingly aims at providing a high-pressure processing apparatus and a high-pressure processing method which cause a high-pressure fluid or a mixture of a high-pressure fluid and a chemical agent, as a processing fluid, to come into contact with a surface of an object-to-be-processed to perform a predetermined surface treatment for the surface of the object-to-be-processed while uniformity and throughput of the surface treatment can be enhanced.

### DISCLOSURE OF THE INVENTION

The present invention relates to a high-pressure processing apparatus and a high-pressure processing method which cause a high-pressure fluid or a mixture of a high-pressure fluid and a chemical agent, as a processing fluid, to come into contact with a surface of an object-to-be-processed, thereby performing a predetermined surface treatment for the surface of the object-to-be-processed. In order to achieve the abovementioned aim, the present invention is structured as follows.

The high-pressure processing apparatus according to the present invention comprises a pressure vessel having a processing chamber therein for performing the surface treatment; holding means for holding the object-to-be-processed inside the processing chamber; and a plurality of introducing means for introducing the processing fluid into the processing chamber to supply the processing fluid onto the surface of the object-to-be-processed. In the invention structured in this manner, a plurality of introducing means are provided so that the processing fluid flows from a plurality of points along the surface of the object-to-be-processed. As a result, because agitation at the surface of the object-to-be-processed is actively encouraged in the present invention as compared with a conventional technique of supplying a simple laminar flow to perform the surface treatment, it is possible to enhance uniformity of the surface treatment and drastically reduce processing time, i.e. enhance throughput.

The high-pressure processing apparatus according to the present invention comprises a pressure vessel having a processing chamber therein for performing the surface treatment; holding means for holding the object-to-be-processed inside the processing chamber; introducing means for introducing the processing fluid into the processing chamber to supply the processing fluid onto the surface of the object-to-be-processed; and rotating means for rotating the object-to-be-processed, which is held by the holding means, inside the processing chamber. In the invention structured in this manner, the processing fluid supplied from the introducing means flows into along the surface of the object-to-be-processed which is being rotated by the rotating means. As a result, by interaction between a rotating action of the object-to-be-processed and a flowing action of the processing fluid along the surface of the object-to-be-processed, agitation of the processing fluid at the surface of the object-to-be-processed is encouraged and exchange of the processing fluid is actively expedited. Therefore, it is possible to enhance uniformity of the surface treatment and drastically reduce processing time, i.e. enhance throughput.

The high-pressure processing apparatus according to the present invention comprises a pressure vessel having a processing chamber therein for performing the surface treatment; holding means for holding the object-to-be-processed inside the processing chamber; introducing means for introducing the processing fluid into the processing chamber to supply the processing fluid onto the surface of the object-to-be-processed; and agitating means for agitating the processing fluid supplied into the processing chamber. In the invention structured in this manner, the processing fluid supplied from the introducing means is supplied onto the surface of the object-to-be-processed as it is agitated by the agitating means. As a result, by interaction between an agitating action of the processing fluid and a flowing action of the processing fluid along the surface of the object-to-be-processed, agitation of the processing fluid at the surface of the object-to-be-processed is encouraged and exchange of the processing fluid is actively expedited. Therefore, it is possible to enhance uniformity of the surface treatment and drastically reduce processing time, i.e. enhance throughput.

The high-pressure processing method according to the present invention forms a whirling flow of the processing fluid over the surface of the object-to-be-processed. In the invention structured in this manner, the processing fluid is not only supplied onto the surface of the object-to-be-processed, but also the whirling flow of the processing fluid is formed over the surface of the object-to-be-processed and the processing fluid comes into contact with the surface of the object-to-be-processed, thereby performing the predetermined surface treatment (e.g. developing, cleaning, drying or the like). Therefore, because agitation at the surface of the object-to-be-processed is actively encouraged in the present invention as compared with a conventional technique of supplying a simple laminar flow to perform the surface treatment, it is possible to enhance uniformity of the surface treatment and drastically reduce processing time, i.e. enhance throughput.

Further, the high-pressure processing method according to the present invention makes the processing fluid flow along the surface of the object-to-be-processed in a predetermined direction while providing disturbance to the processing fluid to agitate the processing fluid within the surface of the object-to-be-processed. In the invention structured in this manner, the processing fluid flows along the surface of the object-to-be-processed in the predetermined direction, but then the disturbance is provided to the processing fluid to agitate the processing fluid within the surface of the object-to-be-processed. In this manner, the processing fluid in an agitated state comes into contact with the surface of the object-to-be-processed, thereby performing the predetermined surface treatment (e.g. developing, cleaning and drying). Therefore, because exchange of the processing fluid is actively expedited in addition to the agitation thereof in the present invention, it is possible to enhance uniformity of the surface treatment and drastically reduce processing time, i.e. enhance throughput as compared with a conventional technique of supplying a simple laminar flow to perform the surface treatment.

“A surface of an object-to-be-processed” in the present invention denotes a surface which should be subjected to a high-pressure process. In the case where the object-to-be-processed is one of various types of substrates such as a semiconductor wafer, a glass substrate for photomask, a glass substrate for liquid crystal display, a glass substrate for plasma display and an optical disk substrate, when it is necessary to carry out the high-pressure process for a first principal surface which is formed with a circuit pattern and the like out of both principal surfaces of the substrate, the first principal surface corresponds to “a surface of an object-to-be-processed” in the present invention. On the other hand, when it is necessary to carry out the high-pressure process for a second principal surface, the second principal surface corresponds to “a surface of an object-to-be-processed” in the present invention. When it is necessary to carry out the high-pressure process for both principal surfaces as in the case of a substrate populated on both principal surfaces, each of the both principal surfaces corresponds to “a surface of an object-to-be-processed” in the present invention, of course.

Cited as a representative example of a surface treatment in the present invention is a cleaning process for unsticking and removing a contaminant from the object-to-be-processed adhered with the contaminant such as a semiconductor substrate adhered with a resist. The object-to-be-processed is not limited to a semiconductor substrate, but denotes various types of base materials made of metal, plastic, ceramics or the like on which discontinuous or continuous layers made of materials different therefrom are formed or remain. The high-pressure processing apparatus and the high-pressure processing method of the present invention target not only the cleaning process but also all of processes for removing unnecessary materials from on the object-to-be-processed with the use of a high-pressure fluid and a chemical agent other than the high-pressure fluid (e.g. drying, developing or the like).

The high-pressure fluid used in the present invention is preferably carbon dioxide because of its safety, price and easiness of changing into a supercritical state. Other than carbon dioxide, water, ammonia, nitrogen monoxide, ethanol or the like may be used. The reasons why the high-pressure fluid is used are as follows. The high-pressure fluid has a high diffusion coefficient so that it is possible to disperse a dissolved contaminant into a medium. In addition, when the high-pressure fluid is changed into a supercritical fluid by bringing higher pressure thereon, it is possible to more penetrate even through fine patterns due to its property between gas and liquid. Further, density of the high-pressure fluid is close to that of liquid so that it is possible to contain a far larger amount of an additive (chemical agent) in comparison with gas.

The high-pressure fluid in the present invention is a fluid whose pressure is 1 MPa or more. The high-pressure fluid preferably used is a fluid which is known to possess high density, high solubility, low viscosity and high diffusion property, and further preferably used is a fluid which is in a supercritical or subcritical state. In order to bring carbon dioxide into a supercritical fluid, carbon dioxide may be at 31 degrees Celsius and of 7.1 MPa or more. It is preferable to use a subcritical fluid (high-pressure fluid) or supercritical fluid of 5 through 30 MPa at cleaning, and a rinsing step, a drying/developing step and the like after the cleaning, and it is further preferable to perform these processes under 7.1 through 20 MPa. Although the case where a cleaning process and a drying process are performed as a surface treatment will be described in “BEST MODES FOR PRACTICING THE INVENTION” below, a high-pressure process is not limited to the cleaning process and the drying process.

Since a high molecular contaminant, such as a resist and an etching polymer adhering to the semiconductor substrate, is also removed in the present invention, the cleaning process is executed with a chemical agent added, considering that a processing fluid comprised merely of a high-pressure fluid such as carbon dioxide has only insufficient detergency. With respect to the chemical agent, a basic compound is preferably used as a cleaning component. This is because a basic compound has a hydrolysis function of a high molecular substance which is very often used as a resist, and accordingly achieves effective cleaning. Specific examples of a basic compound are one or more types of compounds selected from a group consisting of quaternary ammonium hydroxide, quaternary ammonium fluoride, alkyl amine, alkanolamine, hydroxyl amine (NH₂OH) and ammonium fluoride (NH₄F). It is preferable that the cleaning component is contained in the amount of 0.05 through 8 percent by mass to the high-pressure fluid. When the high-pressure processing apparatus according to the present invention is used for the purpose of drying or developing, xylene, methyl isobutyl ketone, a quaternary ammonium compound, fluorine-containing polymer or the like may be added as a chemical agent depending on a property of a resist which is to be dried or developed.

When the cleaning component such the basic compound as the one described above has a low degree of solubility in the high-pressure fluid, it is preferable to use, as a second chemical agent, a compatibilizer which can serve as an auxiliary agent dissolving or evenly diffusing the cleaning component in the high-pressure fluid. The compatibilizer also has a function of preventing re-adhesion of a contaminant during a rinsing step which is after completion of a cleaning step.

Although not particularly limited as long as compatibilizing the cleaning component with the high-pressure fluid, the compatibilizer is preferably alcohol such as methanol, ethanol and isopropanol or alkyl sulfoxides such as dimethyl sulfoxide. At the cleaning step, the compatibilizer may be appropriately selected within 50 percent by mass or less to the high-pressure fluid.

### BRIEF DESCRIPTION OF THE DIAGRAMS

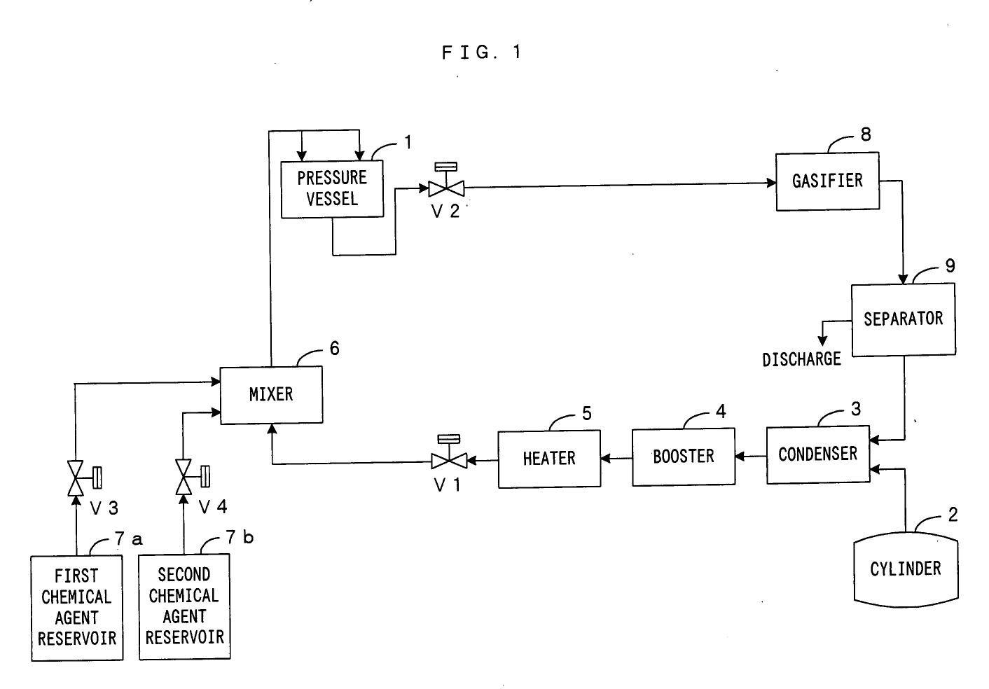

FIG. 1 is a diagram showing an entire structure of a first embodiment of a high-pressure processing apparatus according to the present invention;

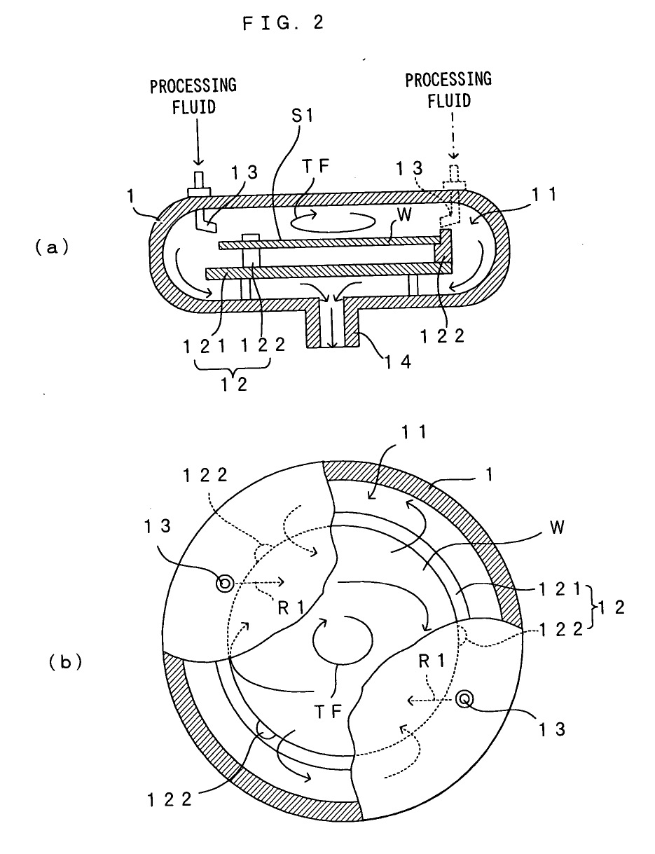

FIG. 2 is a group of diagrams showing a pressure vessel and an inner structure thereof in the high-pressure processing apparatus shown in FIG. 1;

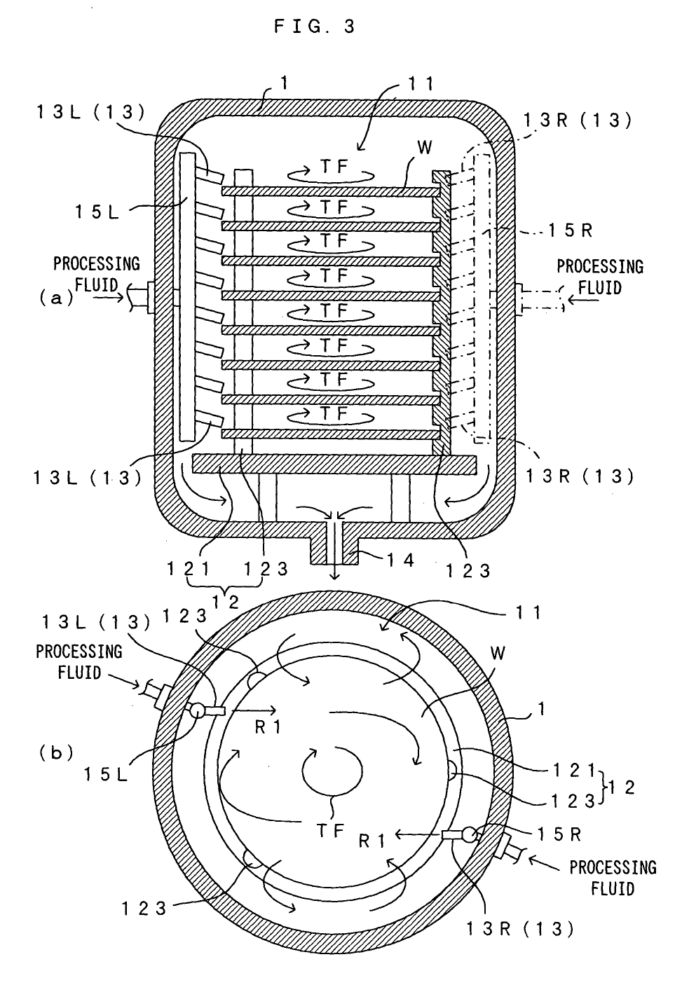

FIG. 3 is a group of diagrams showing a pressure vessel and an inner structure thereof adopted in a second embodiment of the high-pressure processing apparatus according to the present invention;

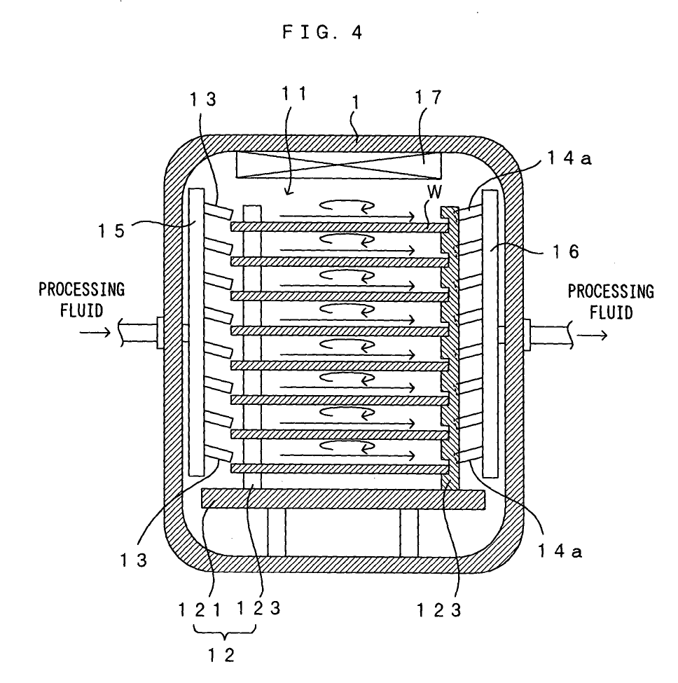

FIG. 4 is a diagram showing a pressure vessel and an inner structure thereof adopted in a third embodiment of the high-pressure processing apparatus according to the present invention;

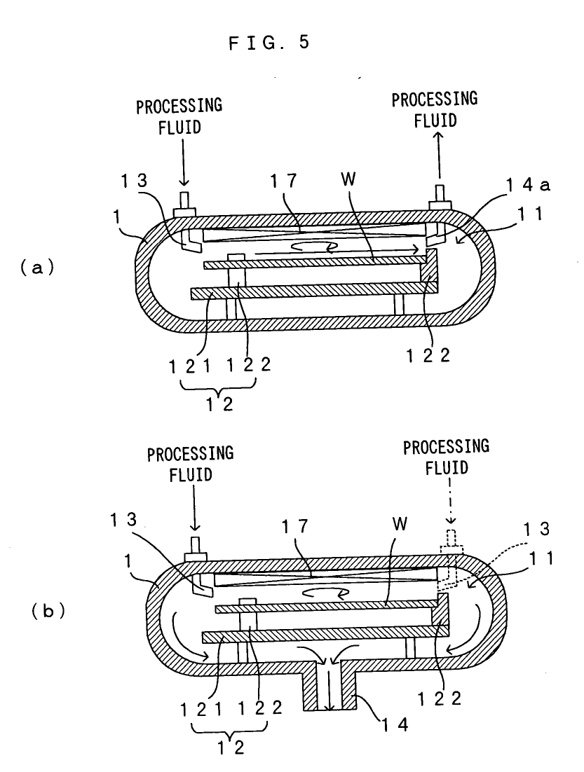

FIG. 5 is a group of diagrams showing a fourth embodiment of the high-pressure processing apparatus according to the present invention;

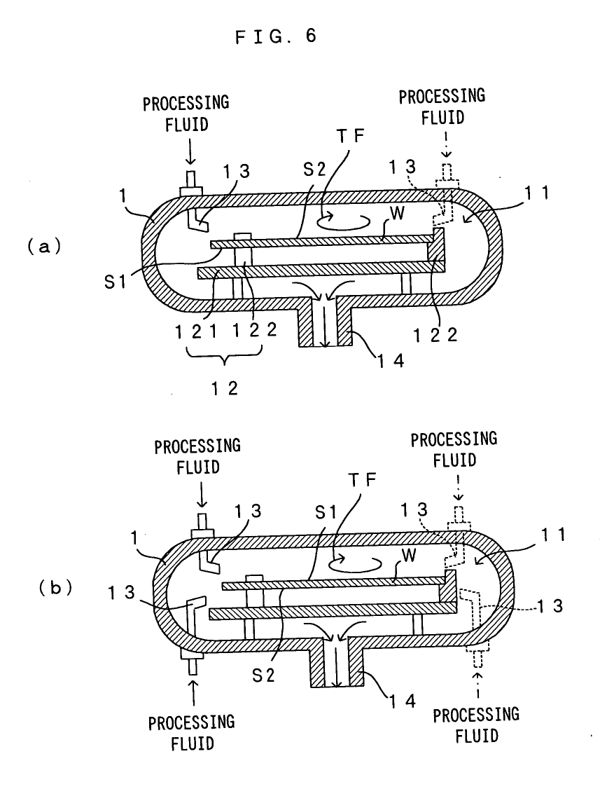

FIG. 6 is a group of diagrams showing fifth and sixth embodiments of the high-pressure processing apparatus according to the present invention;

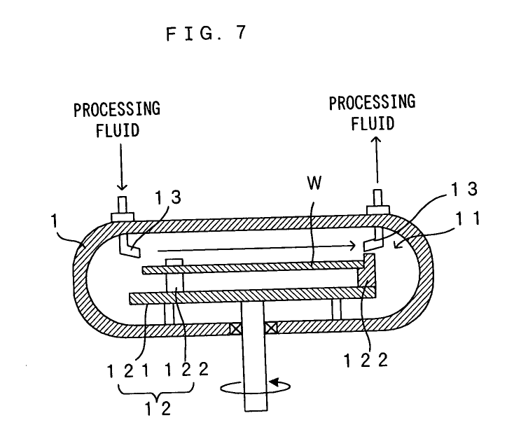

FIG. 7 is a diagram showing a seventh embodiment of the high-pressure processing apparatus according to the present invention;

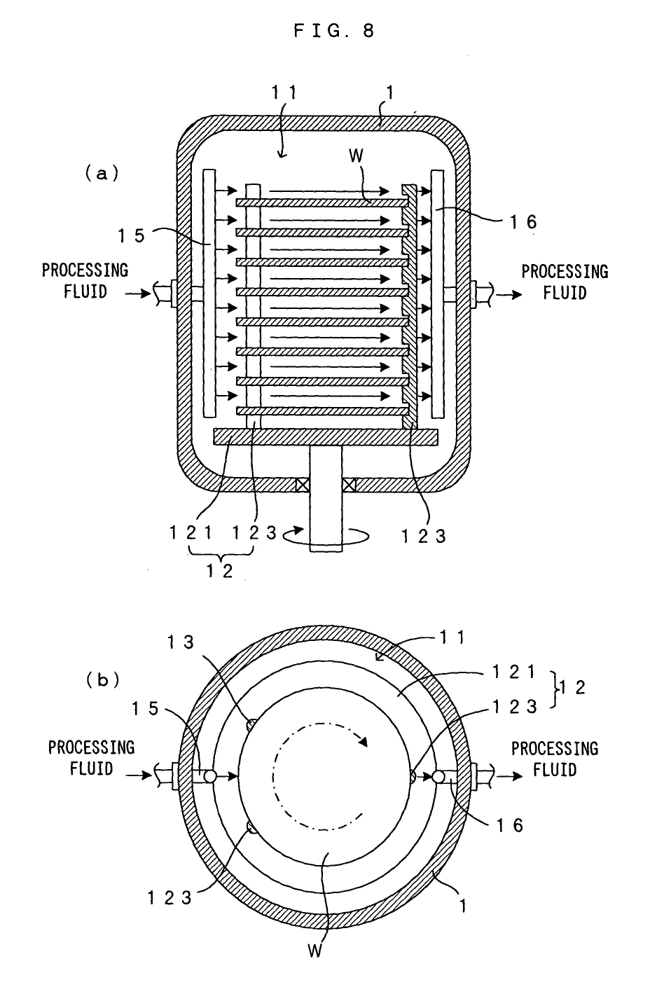

FIG. 8 is a group of diagrams showing an eighth embodiment of the high-pressure processing apparatus according to the present invention;

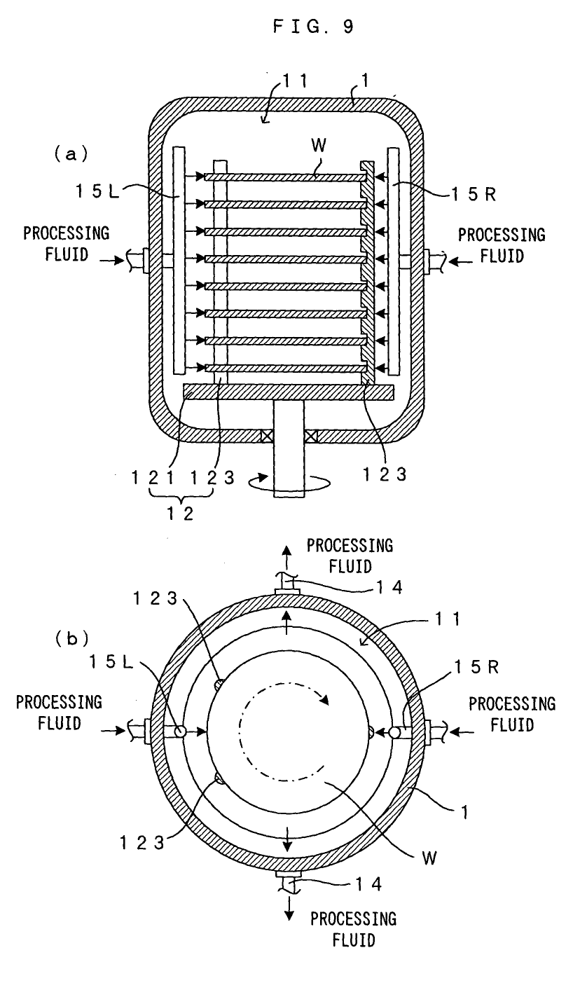

FIG. 9 is a group of diagrams showing a ninth embodiment of the high-pressure processing apparatus according to the present invention;

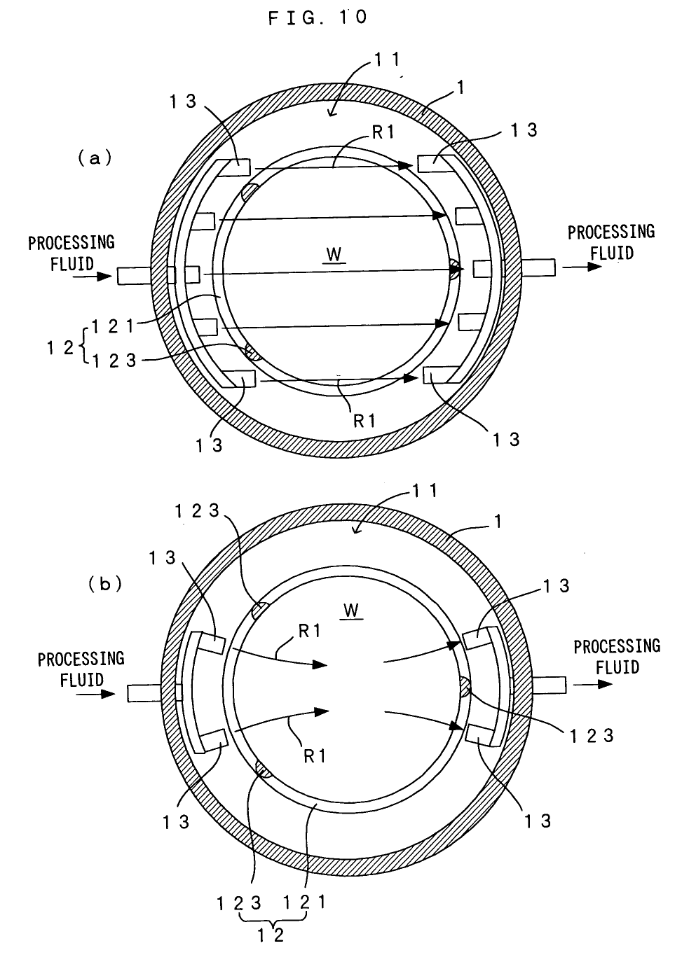

FIG. 10 is a group of diagrams showing a tenth embodiment of the high-pressure processing apparatus according to the present invention; and

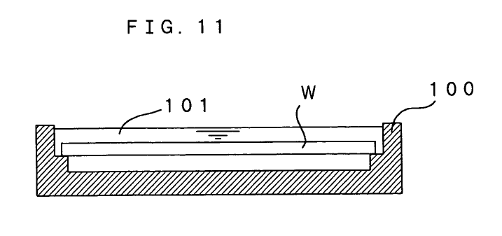

FIG. 11 is a diagram showing transportation of a substrate.

### BEST MODES FOR PRACTICING THE INVENTION

FIG. 1 is a diagram showing an entire structure of a first embodiment of a high-pressure processing apparatus according to the present invention. FIG. 2 is a group of diagrams showing a pressure vessel and an inner structure thereof in the high-pressure processing apparatus shown in FIG. 1. This high-pressure processing apparatus is an apparatus which introduces supercritical carbon dioxide (high-pressure fluid) or a mixture of supercritical carbon dioxide and a chemical agent, as a processing fluid, into a processing chamber 11 which is formed inside a pressure vessel 1, thereby performing predetermined cleaning and drying processes for a subround substrate (object-to-be-processed) W, such as a semiconductor wafer, which is held in the processing chamber 11. Hereinafter, structure and operation of the high-pressure processing apparatus will be described in detail.

In the high-pressure processing apparatus, while supercritical carbon dioxide is cyclically used, liquid carbon dioxide is supplied from a cylinder 2 when carbon dioxide inside the system decreases as the processing chamber 11 is opened to an atmospheric pressure or on other occasions. The cylinder 2 is connected with a condenser 3 comprising a condenser and the like, and carbon dioxide is reserved as a liquid fluid under pressure of 5 through 6 MPa in the cylinder 2. The liquid carbon dioxide is pumped from the cylinder 2 by a pump (not shown), and supplied into the system through the condenser 3.

A booster 4 such as a pressure pump is connected to an output side of the condenser 3. High-pressure liquid carbon dioxide is obtained as liquid carbon dioxide is pressurized in the booster 4, and high-pressure liquid carbon dioxide is sent under pressure to a mixer 6 via a heater 5 and a high-pressure valve V1.

High-pressure liquid carbon dioxide thus sent under pressure is heated by the heater 5 to a temperature which is suitable to a surface treatment (cleaning and drying), accordingly becomes supercritical carbon dioxide and is then sent to the mixer 6 via the high-pressure valve V1.

Connected with the mixer 6 are two types of chemical agent reservoirs for storing and supplying chemical agents which are suitable for a surface treatment of the substrates W, namely, a first chemical agent reservoir 7a and a second chemical agent reservoir 7b respectively through high-pressure valves V3 and V4. Because of this, as the high-pressure valves V3 and V4 are opened and closed under control, a first chemical agent from the first chemical agent reservoir 7a and a second chemical agent from the second chemical agent reservoir 7b are supplied, each in a quantity corresponding to the controlled opening and closing, to the mixer 6, and the quantities of mixing the chemical agents with supercritical carbon dioxide are adjusted. Thus, according to this embodiment, it is possible to selectively prepare “supercritical carbon dioxide”, “supercritical carbon dioxide+first chemical agent”, “supercritical carbon dioxide+second chemical agent” and “supercritical carbon dioxide+first chemical agent+second chemical agent” as the processing fluid, and supply the same to the processing chamber 11 of the pressure vessel 1. Furthermore, with a controller (not shown) appropriately controlling the high-pressure valves V3 and V4 to open and close in accordance with the contents of the surface treatment, it is possible to select the type of the processing fluid, and control densities of the chemical agents.

As shown in FIG. 2, a substrate holder 12 for holding the substrate W is disposed inside the pressure vessel 1, that is, in the processing chamber 11. The substrate holder 12 consists of a holder body 121, which is fastened to an inner bottom of the pressure vessel 1, and three support pins 122, which are provided in an extended condition upward from a top surface of the holder body 121. By means of the three support pins 122, the substrate holder 12 can support outer edges of a single substrate W with its surface S1 to be performed with the surface treatment (high-pressure process) turned up. After a gate valve (not shown) disposed in a side surface portion of the pressure vessel 1 is opened and a transportation robot loads a single substrate W yet to be processed onto the substrate holder 12 via the gate valve, the gate valve is closed and the surface treatment is performed as described later. Meanwhile, after the surface treatment, the gate valve is opened and the transportation robot unloads the processed substrate W. Thus, according to this embodiment, the high-pressure processing apparatus is an apparatus of the so-called single processing system which holds a single substrate W at a time and performs a predetermined surface treatment.

Two supply nozzles 13, 13 are fixed to a top surface of the pressure vessel 1, and emit the processing fluid sent from the mixer 6 toward the surface of the substrate W which is held by the substrate holder 12. Especially, according to this embodiment, as shown in FIG. 2, the supply nozzles 13, 13 are disposed so that flow directions R1 of the processing fluid supplied from the respective supply nozzles 13, 13 deviate from each other within the surface S1 of the substrate W (space of FIG. 2(b)) and approximately parallel to a direction of a tangent to the substrate W. As indicated by arrows in FIG. 2, the processing fluid forms a whirling flow TF over the surface S1 of the substrate W. Thus, according to this embodiment, the supply nozzles 13, 13 serve as introducing means for supplying the processing fluid to the surface S1 of the substrate W which is held by the substrate holder (holding means) 12.

In addition, an exhaust port 14 is disposed to an under surface of the pressure vessel 1, so that the processing fluid or a contaminant which is generated through a surface treatment inside the processing chamber 11 can be discharged outside the pressure vessel 1.

A gasifier 8 formed by a decompressor or the like is connected with the exhaust port 14 of the pressure vessel 1 structured in this manner via a high-pressure valve V2, and through a decompression process, the fluid discharged from the processing chamber 11 through the exhaust port 14 (processing fluid+contaminant and the like) is completely gasified and fed to a separator 9. The separator 9 performs gas-liquid separation, thereby obtaining carbon dioxide as a gas component and a mixture of a contaminant and a chemical agent as a liquid component. At this moment, the contaminant may be precipitated as a solid and separated as it is mixed in the chemical agent. The separator 9 may be various types of apparatuses capable of performing gas-liquid separation, such as simple distillation, distillation (fraction) and flash separation, a centrifugal machine, etc.

Thus, this embodiment requires the gasifier 8 to completely gasify the fluid (processing fluid+contaminant and the like) discharged from the processing chamber 11 before the fluid is fed to the separator 9. This is for the purpose of improving efficiency of separation and efficiency of recycling carbon dioxide in the separator 9 because decompressed fluid such as carbon dioxide becomes a mixture of a gas-like fluid (carbonic acid gas) and a liquid-like fluid (liquefied carbon dioxide) in relation to a temperature.

The liquid (or solid) component comprised of a cleaning component or a compatibilizer which is separated in the separator 9 and contains a contaminant is discharged from the separator 9, and post-processed in accordance with necessity. On the other hand, carbon dioxide which is the gas component is supplied to the condenser 3 to be re-used.

Next, the operation of the high-pressure processing apparatus having such a structure as above will be described. The high-pressure processing apparatus is an apparatus in which received is a substrate W, which has been performed with a previous process, e.g. a developing process using a developing fluid in a developing step, and then a controller controls the respective portions of the apparatus in accordance with a program stored in a memory (not shown) of the controller in advance, thereby executing a cleaning step, a rinsing step and a drying step in this order. The operation is as follows.

First, the gate valve disposed in the side surface portion of the pressure vessel 1 is opened. A single substrate W yet to be processed is loaded in by the transportation robot through the gate valve, and as the substrate W is placed on the substrate holder 12 with the surface S1 to be performed with the surface treatment (high-pressure process) turned up, the support pins 122 of the substrate holder 12 hold the substrate W. As holding of the substrate is completed and the transportation robot retreats from the processing chamber 11, the gate valve is closed and the cleaning step is carried out.

In the cleaning step, liquefied carbon dioxide within the system is pressurized in the booster 4 to generate high-pressure liquefied carbon dioxide, and further, while the high-pressure liquefied carbon dioxide is heated in the heater 5 to generate supercritical carbon dioxide, the high-pressure valve V1 is opened to feed the supercritical carbon dioxide to the mixer 6. Both of the high-pressure valves V3 and V4 for chemical agents are opened to make the first chemical agent reservoir 7a and the second chemical agent reservoir 7b to supply mode, and then the first chemical agent is sent under pressure from the first chemical agent reservoir 7a to the mixer 6 and the first chemical agent is sent under pressure from the second chemical agent reservoir 7b to the mixer 6. As a result of this, these first and the second chemical agents are mixed with supercritical carbon dioxide, thereby preparing the processing fluid suitable for the cleaning process.

The processing fluid prepared in the mixer 6 is emitted from the supply nozzles 13, 13 of the pressure vessel 1 toward the surface S1 of the substrate W which is held by the substrate holder 12. At this moment, according to this embodiment, because the flow directions R1 of the processing fluid supplied from the respective supply nozzles 13, 13 deviate from each other within the surface S1 of the substrate W (space of FIG. 2(b)) as described above, the whirling flow TF of the processing fluid is formed over the surface S1 of the substrate W and come into contact with the surface S1 of the substrate W to perform the predetermined cleaning process. Incidentally, the high-pressure valve V2 located downstream from the processing chamber 11 is closed during the cleaning step.

By this cleaning step, the contaminant which has adhered to the substrate W is dissolved in the processing fluid which is in the processing chamber 11 (supercritical carbon dioxide+first chemical agent+second chemical agent). Assuming that the first chemical agent is the cleaning component and the second chemical agent is the compatibilizer, since the contaminant has dissolved in supercritical carbon dioxide owing to the actions of the cleaning component (first chemical agent) and the compatibilizer (second chemical agent), there is a possibility that the dissolved contaminant will precipitate if supercritical carbon dioxide alone is allowed to flow in the processing chamber 11. Hence, it is desirable to execute a first rinsing step, which uses a first rinsing processing fluid comprised of supercritical carbon dioxide and the compatibilizer, and a second rinsing step, which uses a second rinsing processing fluid comprised of only supercritical carbon dioxide, in this order after the cleaning step.

Noting this, this embodiment requires to close the high-pressure valve V3 and accordingly bring the first chemical agent reservoir 7a into a supply stop mode as a predetermined period of time elapses since the start of the supplying of the first and the second chemical agents, i.e., the start of the cleaning step, and thereafter stop the pressure-feeding of the first chemical agent (cleaning component) into the mixer 6 from the first chemical agent reservoir 7a, consequently mix supercritical carbon dioxide with the compatibilizer in the mixer 6 and prepare the first rinsing processing fluid, and supply the first rinsing processing fluid to the processing chamber 11. At the same time, the high-pressure valve V2 is opened. This allows the first rinsing processing fluid to flow in the processing chamber 11 and the cleaning component and the contaminant within the processing chamber 11 to gradually decrease, eventually leading to a state that the processing chamber 11 is filled up with the first rinsing processing fluid (supercritical carbon dioxide+compatibilizer).

As the first rinsing step is completed, the second rinsing step is carried out. At the second rinsing step, the high-pressure valve V4 is additionally closed to bring the second chemical agent reservoir 7b into the supply stop mode, the pressure-feeding of the second chemical agent (compatibilizer) into the mixer 6 from the second chemical agent reservoir 7b is stopped, and supercritical carbon dioxide alone is supplied to the processing chamber 11 as the second rinsing processing fluid. The second rinsing processing fluid consequently flows in the processing chamber 11, and the processing chamber 11 gets filled up with the second rinsing processing fluid (supercritical carbon dioxide).

Following this, the high-pressure valve V1 is closed for decompression, and the drying process of the substrate W is executed. After the processing chamber 11 returns to the atmospheric pressure, the gate valve disposed in the side surface portion of the pressure vessel 1 is opened. The transportation robot then unloads the processed substrate W through the gate valve, and a series of processes (cleaning+first rinsing+second rinsing+drying) completes. When a subsequent substrate yet to be processed is transported, the operation above is repeated.

As described above, according to this embodiment, because a plurality of supply nozzles 13, 13 supply the processing fluid toward the surface S1 of the substrate W, the processing fluid flows along the surface S1 of the substrate W from a plurality of points and comes into contact with the surface S1 of the substrate W, thereby performing a predetermined surface treatment. Therefore, it is possible to enhance uniformity of the surface treatment and drastically reduce processing time, i.e. enhance throughput as compared with a conventional technique for performing the surface treatment by simply supplying a laminar flow.

Further, according to this embodiment, because the processing fluid is not only supplied from a plurality of points, but also the flow directions of the processing fluid supplied from the respective supply nozzles 13, 13 deviate from each other within the surface S1 of the substrate W, the whirling flow TF of the processing fluid is formed over the surface S1 of the substrate W and the processing fluid comes into contact with the surface S1 of the substrate W, thereby performing a predetermined surface treatment (e.g. cleaning, first rinsing, second rinsing, drying). Therefore, it is possible to further enhance the uniformity and the throughput of the surface treatment.

FIG. 3 is a group of diagrams showing a pressure vessel and an inner structure thereof in a second embodiment of the high-pressure processing apparatus according to the present invention. The high-pressure processing apparatus according to the second embodiment is an apparatus of the so-called batch processing system in which while a substrate holder (holding means) 12 holds a plurality of substrates W at a time, a predetermined surface treatment (e.g. cleaning, first rinsing, second rinsing, drying) is performed for the respective substrates W. In this respect, the second embodiment is greatly different from the first embodiment of the single processing system.

That is, in this second embodiment, as shown in FIG. 3(a), support columns 123 of the substrate holder 12 hold a plurality of substrates W (eight substrates W in this embodiment) which are in a state of separating from each other and being stacked on top of each other in layers. For each of the plurality of substrates W held in this manner, two supply nozzles 13, 13 are provided, respectively.

Out of these supply nozzles 13, supply nozzles 13L disposed on the left hand of FIG. 3(b) are communicated and connected with a side surface of a supply tube 15L which extends along the direction of stacking layers of the substrates W. The processing fluid supplied from the mixer 6 is led to the respective supply nozzles 13L via the supply tube 15L, and emitted from the respective supply nozzles 13L toward the surfaces of the substrates W corresponding thereto. Supply nozzles 13R disposed on the right hand of FIG. 3(b) are communicated and connected with a side surface of a supply tube 15R which extends along the direction of stacking layers of the substrates W. The processing fluid supplied from the mixer 6 is led to the respective supply nozzles 13R via the supply tube 15R, and emitted from the respective supply nozzles 13R toward the surfaces of the substrates W corresponding thereto. Additionally, in this embodiment as well as the first embodiment, each of a pair of supply nozzles 13L, 13R provided for each of the substrates W are disposed so that flow directions R1, R1 of the processing fluid supplied from the respective supply nozzles 13L, 13R deviate from each other within the surface S1 of the substrate W. Since other essential structures are the same as those of the first embodiment, the same structures will be denoted at the same reference symbols but will not be described again.

In the high-pressure processing apparatus structured in this manner as well, substrates W yet to be processed are loaded into the processing chamber 11 by a transportation robot, and then the cleaning step, the first rinsing step, the second rinsing step and the drying step are executed in this order as in the first embodiment. When the processing fluid is supplied to the processing chamber 11 during the respective steps, the flow directions R1, R1 of the processing fluid emitted from the supply nozzles 13L, 13R provided for the respective substrates W deviate from each other. As a result, a similar effect to that according to the first embodiment is realized in any of the substrates W. That is, since the processing fluid is supplied toward the surfaces of the substrates W from a plurality of supply nozzles 13, 13 provided for the respective substrates W, the processing fluid flows along the surfaces of the substrates W from a plurality of points and comes into contact with the surfaces of the substrates W, thereby performing a predetermined surface treatment. Therefore, it is possible to enhance uniformity of the surface treatment and drastically reduce processing time, i.e. enhance throughput as compared with a conventional technique for performing the surface treatment by simply supplying a laminar flow.

In addition, according to this embodiment, because the processing fluid is not only supplied from a plurality of points, but also the whirling flow TF of the processing fluid is formed over each of the surfaces of the substrates W and the processing fluid comes into contact with each of the surfaces of the substrates W, thereby performing a predetermined surface treatment (e.g. cleaning, first rinsing, second rinsing, drying). Therefore, it is possible to further enhance the uniformity and the throughput of the surface treatment.

Further, in the high-pressure processing apparatus of the batch processing system shown in FIG. 3, the processing fluid comes into contact with not only an upward first principal surface of both principal surfaces of each substrate W, but also a downward second principal surface, thereby performing a series of the surface treatments mentioned above for the both principal surfaces at a time.

FIG. 4 is a diagram showing a pressure vessel in a third embodiment of the high-pressure processing apparatus according to the present invention. The high-pressure processing apparatus according to the third embodiment is an apparatus of the so-called batch processing system in which while a substrate holder (holding means) 12 holds a plurality of substrates W at a time, a predetermined surface treatment (e.g. cleaning, first rinsing, second rinsing, drying) is performed for the respective substrates W. The third embodiment is the same in this respect as the second embodiment of the batch processing system, but greatly different in a supply system of the processing fluid. Hereinafter, with a focus on the differences with the second embodiment, the structure and operation of the third embodiment will be described.

In this third embodiment, just like in the second embodiment, as shown in FIG. 4, the support columns 123 of the substrate holder 12 hold a plurality of substrates W which are in a state of separating from each other and being stacked on top of each other in layers. However, the third embodiment is greatly different from the second embodiment in nozzle structure and arrangement relation. That is, in the third embodiment, with regard to each of the plurality of substrates W, two nozzles 13, 14a corresponding to the substrate W are disposed on the opposite sides of symmetry central axis of the substrate W from each other. The nozzle 13 out of these nozzles is a supply nozzle for supplying the processing fluid, and the other nozzle 14a is an exhaust nozzle for exhausting the processing fluid flowing along the surface of the substrate W. The nozzle 14a is communicated and connected with a side surface of an exhaust tube 16, and able to discharge the processing fluid to the gasifier 8 via the high-pressure valve V2.

Therefore, in the high-pressure processing apparatus structured in this manner, the processing fluid supplied from the mixer 6 (shown in FIG. 1) is branched into the respective supply nozzles 13 via the supply tube 15, and emitted toward the surface sides of the substrates W to flow toward the side of the exhaust nozzles 14. Then, the exhaust nozzles 14 draw in the coming processing fluid and discharge it to the gasifier 8 via the exhaust tube 16.

Simple provision of the supply nozzle 13 and the exhaust nozzle 14a for each of the substrates W is no more than formation of a laminar flow of the processing fluid over the surface of the substrate W as in the conventional technique. However, in this embodiment, as shown in FIG. 4, a fan 17 is additionally provided on a top surface of the processing chamber 11 to cause a disturbance to the processing fluid flowing along the surfaces of the substrates W, thereby agitating the processing fluid within the surfaces of the substrates W.

In the high-pressure processing apparatus structured as described above as well, substrates W yet to be processed are loaded into the processing chamber 11 by a transportation robot, and then the cleaning step, the first rinsing step, the second rinsing step and the drying step are executed in this order as in the first and the second embodiments. When the processing fluid is supplied to the processing chamber 11 during the respective steps, the processing fluid is emitted from the respective supply nozzles 13 toward the surfaces of the substrates W while the fan 17 is activated to cause a disturbance to the processing fluid flowing along the surfaces of the substrates to be agitated. As a result, as in the first and the second embodiments, the processing fluid in an agitated state comes into contact with the surfaces of the substrates W, thereby performing a predetermined surface treatment (e.g. cleaning, first rinsing, second rinsing, drying). Therefore, it is possible to enhance uniformity of the surface treatment and drastically reduce processing time, i.e. enhance throughput as compared with a conventional technique for performing the surface treatment by simply supplying a laminar flow.

Further, according to this embodiment, by interaction between the agitation of the processing fluid by means of the fan 17 served as “agitating means” in the present invention and the flowing action of the processing fluid along the surfaces of the substrates W, agitation of the processing fluid at the surfaces of the substrates is encouraged and exchange of the processing fluid is actively expedited. Therefore, it is possible to further enhance the uniformity and the throughput of the surface treatment.

Although the fan 17 is disposed on the top surface of the processing chamber 11 in the third embodiment, the locations of disposition and/or the number of fans may be freely determined. Further, Although this third embodiment is directed to an application of the present invention to the high-pressure processing apparatus of the so-called batch processing system, the present invention is also applicable to the high-pressure processing apparatus of the so-called single processing system (fourth embodiment) as shown in FIG. 5, for example.

The present invention is not limited to the embodiments described above, but may be modified in various fashions other than those described above to the extent not deviating from the purpose of the invention. For instance, although two supply nozzles 13, 13 are provided for the respective substrates W in the first and the second embodiments, the number of supply nozzles corresponding to the respective substrates may be more than 2. In short, a similar effect to that according to the first and the second embodiments described above is realized by the structure in which flow directions of the processing fluid supplied from each of a plurality of nozzles corresponding to the respective substrates deviate from each other within the surfaces of the substrates.

In the first embodiment of the single processing system, out of both principal surfaces of the substrate W, a first principal surface S1, which is upward, serves as a “surface” in the present invention and a predetermined surface treatment is performed therefor. However, when the surface treatment is performed for a second principal surface of the substrate W, as shown in FIG. 6(a), the second principal surface S2 may be held in an upward state by support pins 122 (fifth embodiment). When it is necessary to perform the surface treatment for both principal surfaces as in the case of a substrate populated on both principal surfaces, a plurality of supply nozzles 13, 13 may be disposed for each of the principal surfaces S1, S2, as shown in FIG. 6(b) for example (sixth embodiment).

In any of the embodiments described above, while the substrate W held by the substrate holder 12 is fixedly disposed, the processing fluid is supplied to the processing chamber 11 to perform the surface treatment. However, as shown in FIG. 7 or 8 for example, rotating means (not shown) such as a motor may be connected with the substrate holder 12 so as to rotate the substrate W at the same time as, or before or after the suppliance of the processing fluid. This increases the frequency of contact between the substrate surface and the processing fluid, thereby further enhancing processing efficiency. Especially, it is desirable to rotate the substrate W relatively in the direction opposite to the turning direction of a whirling flow formed initially. By interaction between the rotating action of the substrate W and the flowing action of the processing fluid along the surface of the substrate W, agitation of the processing fluid at the surfaces of the substrates is encouraged and exchange of the processing fluid is actively expedited. Therefore, it is possible to further enhance the uniformity and the throughput of the surface treatment. Incidentally, FIG. 7 shows the high-pressure processing apparatus of the single processing system (seventh embodiment), and on the other hand FIG. 8 shows the high-pressure processing apparatus of the batch processing system (eighth embodiment).

Although the processing fluid emitted from the respective supply nozzles 13 is supplied toward the surfaces (principal surfaces) of the substrates W in the embodiments described above, as shown in FIG. 9, the processing fluid may be supplied from the sides of the substrates W (ninth embodiment). By the way, it is needless to say that the processing fluid may be supplied from the side of the substrate W in the high-pressure processing apparatus of the single processing system.

In the embodiments shown in FIGS. 4, 5(a), 7 and 8, the processing fluid supplied from the supply nozzles 13 for the respective substrates W is discharged to the exhaust nozzles 14a corresponding to the respective supply nozzles 13. However, the number and the locations of supply nozzles 13 corresponding to the respective substrates W may be freely determined, and the number and the locations of exhaust nozzles 14a may be freely determined as well. As shown in FIG. 10 for example, for each of the substrates W, a plurality of supply nozzles 13 may be disposed along the circumference of the substrate W, and a plurality of exhaust nozzles 14a may be disposed along the circumference of the substrate W (tenth embodiment). In this instance, the supply nozzles 13 may be disposed so that flow directions R1 of the processing fluid supplied from the supply nozzles 13 are approximately parallel to each other as shown in FIG. 10(a), or the supply nozzles 13 may be disposed so that the flow directions R1 make an acute angle with each other as shown in FIG. 10(b).

Although the substrate W is directly held by the substrate holder 12 in the embodiments described above, as shown in FIG. 11 for example, it is conceivable that the substrate W would be transported as it is housed in a transporting container 100. In this case, the substrate W may be indirectly held by the substrate holder 12 supporting the transporting container 100.

This is applicable not only to the case where the substrate W is simply housed in the transporting container 100, but also to the case where the transporting container 100 is filled with a moisturizing fluid 101, such as deionized water and an organic medium, to transport the substrate as the surface thereof is in a wet state in order to prevent the surface from air drying during the transportation of the substrate.

Although the processing fluid is emitted from the supply nozzles 13 in the embodiments described above, the processing fluid may be sprayed from the supply nozzles 13. In this case, supplied is the processing fluid made into mist, so that processing efficiency can be enhanced.

Although two types of chemical agents are mixed with supercritical carbon dioxide (high-pressure fluid) to prepare the processing fluid in the embodiments described above, the kinds and the number of chemical agents may be freely determined. When the surface treatment is performed not using any chemical agents, the chemical agent reservoirs become unnecessary.

Further, although the cleaning process, the first rinsing process, the second rinsing process and the drying process are performed as the surface treatment in the embodiments described above, the applicable object of the present invention is not limited to the high-pressure processing apparatus which performs all of these processes. The present invention is also applicable to a high-pressure processing apparatus which performs part of these processes, such as an apparatus which receives a substrate processed through the developing step and the cleaning/rinsing step to perform only the drying process, and a high-pressure apparatus which performs another surface treatment (e.g. developing).

Industrial Applicability

As described above, the present invention is applicable to a high-pressure processing apparatus and a high-pressure processing method which cause a high-pressure fluid or a mixture of a high-pressure fluid and a chemical agent, as a processing fluid, to come into contact with a surface of an object-to-be-processed such as a substrate, thereby performing a predetermined surface treatment (e.g. developing, cleaning and drying) for the surface of the object-to-be-processed, and suitable for improvement of uniformity and throughput of the surface treatment. More specifically, because a plurality of introducing means are provided and the processing fluid is supplied from the respective introducing means onto the surface of the object-to-be-processed, the processing fluid from a plurality of points flows along the surface of the object-to-be-processed and comes into contact with the surface of the object-to-be-processed, thereby performing the predetermined surface treatment (e.g. developing, cleaning, drying or the like). Therefore, it is possible to enhance uniformity of the surface treatment and drastically reduce processing time, i.e. enhance throughput as compared with a conventional technique for performing the surface treatment by simply supplying a laminar flow.

According to the present invention, because the processing fluid supplied from the introducing means is supplied onto the surface of the object-to-be-processed which is being rotated by rotating means, the processing fluid flows along the surface of the object-to-be-processed which is being rotated and comes into contact with the surface of the object-to-be-processed, thereby performing the predetermined surface treatment (e.g. developing, cleaning, drying or the like). As a result, by interaction between a rotating action of the object-to-be-processed and a flowing action of the processing fluid along the surface of the object-to-be-processed, agitation of the processing fluid at the surface of the object-to-be-processed can be actively encouraged and exchange of the processing fluid can be expedited. Therefore, it is possible to enhance uniformity of the surface treatment and drastically reduce processing time, i.e. enhance throughput.

According to the present invention, because the processing fluid supplied from the introducing means is supplied onto the surface of the object-to-be-processed as it is agitated by the agitating means, by interaction between an agitating action of the processing fluid and a flowing action of the processing fluid along the surface of the object-to-be-processed, agitation of the processing fluid at the surface of the object-to-be-processed can be encouraged and exchange of the processing fluid can be expedited. Therefore, it is possible to enhance uniformity of the surface treatment and drastically reduce processing time, i.e. enhance throughput.

According to the present invention, the processing fluid is not only simply supplied onto the surface of the object-to-be-processed, but also a whirling flow of the processing fluid is formed over the surface of the object-to-be-processed. Therefore, it is possible to enhance uniformity of the surface treatment and drastically reduce processing time, i.e. enhance throughput as compared with a conventional technique for performing the surface treatment by simply supplying a laminar flow.

Further, according to the present invention, the processing fluid is made to flow along the surface of the object-to-be-processed in a predetermined direction, and provided with disturbance to agitate the processing fluid within the surface of the object-to-be-processed. Therefore, it is possible to enhance uniformity of the surface treatment and drastically reduce processing time, i.e. enhance throughput as compared with a conventional technique for performing the surface treatment by simply supplying a laminar flow.

What is claimed is:

1. A high-pressure processing apparatus which causes a high-pressure fluid or a mixture of a high-pressure fluid and a chemical agent, as a processing fluid, to come into contact with a surface of an object-to-be-processed, thereby performing a predetermined surface treatment for the surface of said object-to-be-processed, the high-pressure processing apparatus comprising:
a pressure vessel having a processing chamber therein for performing said surface treatment;
holding means for holding said object-to-be-processed inside said processing chamber; and
a plurality of introducing means for introducing said processing fluid into said processing chamber to supply said processing fluid onto the surface of said object-to-be-processed.

2. The high-pressure processing apparatus as claimed in claim 1, wherein at least two or more introducing means of said plurality of introducing means are disposed across said object-to-be-processed from each other.

3. The high-pressure processing apparatus as claimed in claim 1, wherein said plurality of introducing means are disposed so that flow directions of said processing fluid supplied from respective introducing means deviate from each other within the surface of said object-to-be-processed.

4. The high-pressure processing apparatus as claimed in any one of claims 1 to 3, wherein at least one of said plurality of introducing means is a nozzle for spraying said processing fluid toward said object-to-be-processed.

5. A high-pressure processing apparatus which causes a high-pressure fluid or a mixture of a high-pressure fluid and a chemical agent, as a processing fluid, to come into contact with a surface of an object-to-be-processed, thereby performing a predetermined surface treatment for the surface of said object-to-be-processed, the high-pressure processing apparatus comprising:
a pressure vessel having a processing chamber therein for performing said surface treatment;
holding means for holding said object-to-be-processed inside said processing chamber;
introducing means for introducing said processing fluid into said processing chamber to supply said processing fluid onto the surface of said object-to-be-processed; and
rotating means for rotating said object-to-be-processed, which is held by said holding means, inside said processing chamber.

6. A high-pressure processing apparatus which causes a high-pressure fluid or a mixture of a high-pressure fluid and a chemical agent, as a processing fluid, to come into contact with a surface of an object-to-be-processed, thereby performing a predetermined surface treatment for the surface of said object-to-be-processed, the high-pressure processing apparatus comprising:
a pressure vessel having a processing chamber therein for performing said surface treatment;
holding means for holding said object-to-be-processed inside said processing chamber;
introducing means for introducing said processing fluid into said processing chamber to supply said processing fluid onto the surface of said object-to-be-processed; and
agitating means for agitating said processing fluid supplied into said processing chamber.

7. The high-pressure processing apparatus as claimed in claim 5 or 6, wherein said introducing means is a nozzle for spraying said processing fluid toward said object-to-be-processed.

8. The high-pressure processing apparatus as claimed in any one of claims 1 to 7, wherein said introducing means supplies said processing fluid toward said object-to-be-processed, which is held by said holding means, from a side of said object-to-be-processed.

9. The high-pressure processing apparatus as claimed in any one of claims 1 to 7, wherein said introducing means is a nozzle for supplying said processing fluid toward said object-to-be-processed.

10. The high-pressure processing apparatus as claimed in any one of claims 1 to 9, wherein said object-to-be-processed is a substrate, and said holding means holds said substrate singly.

11. The high-pressure processing apparatus as claimed in any one of claims 1 to 9, wherein said object-to-be-processed is a substrate, and said holding means holds a plurality of substrates which are in a state of separating from each other and being stacked on top of each other in layers.

12. The high-pressure processing apparatus as claimed in any one of claims 1 to 11, wherein said object-to-be-processed is a subround substrate, and said introducing means is disposed so that a flow direction of said processing fluid supplied from said introducing means is adjusted to a direction of a tangent to said subround substrate.

13. The high-pressure processing apparatus as claimed in any one of claims 1 and 3 to 7, further comprising discharging means which is disposed across said object-to-be-processed on the opposite side of said introducing means for discharging said processing fluid, which is supplied from said introducing means, from said pressure vessel.

14. The high-pressure processing apparatus as claimed in any one of claims 1 to 13, wherein said object-to-be-processed is transported into said pressure vessel as said object-to-be-processed whose surface is in a wet state is housed in a transporting container, and said holding means indirectly holds said object-to-be-processed by supporting said transporting container.

15. A high-pressure processing method which causes a high-pressure fluid or a mixture of a high-pressure fluid and a chemical agent, as a processing fluid, to come into contact with a surface of an object-to-be-processed, thereby performing a predetermined surface treatment for the surface of said object-to-be-processed,
wherein a whirling flow of said processing fluid is formed over the surface of said object-to-be-processed.

16. A high-pressure processing method which causes a high-pressure fluid or a mixture of a high-pressure fluid and a chemical agent, as a processing fluid, to come into contact with a surface of an object-to-be-processed, thereby performing a predetermined surface treatment for the surface of said object-to-be-processed,
wherein said processing fluid flows along the surface of said object-to-be-processed in a predetermined direction, and disturbance is provided to said processing fluid to agitate said processing fluid within the surface of said object-to-be-processed.
